(19) United States
(12) Patent Application Publication
(10) Pub. No.: US 2025/0185437 A1
(43) Pub. Date: Jun. 5, 2025

(54) DISPLAY PANEL AND DISPLAY DEVICE

(71) Applicant: Yungu (Gu’an) Technology Co., Ltd., Langfang (CN)

(72) Inventor: Qiang LIU, Langfang (CN)

(73) Assignee: Yungu (Gu’an) Technology Co., Ltd., Langfang (CN)

(21) Appl. No.: 19/053,380

(22) Filed: Feb. 13, 2025

(30) Foreign Application Priority Data
Mar. 5, 2024 (CN) 202410250937.8

(51) Int. Cl. H10H 29/855

(52) U.S. Cl. CPC H10H 29/855

(57) ABSTRACT

The present application provides a display panel and a display device. The display panel includes pixel regions and light-transmitting regions, and the light-transmitting regions are located between adjacent pixel regions; the light-transmitting regions each include an adjustment sub-region; and the transmittance of a light adjustment layer in the adjustment sub-region to light of a preset color is greater than the transmittance of the light adjustment layer in regions in the light-transmitting region other than the adjustment sub-region to the light of the preset color. In this way, by increasing the transmittance to the light of the preset color in the adjustment sub-region in the light-transmitting region, the color of the light being transmitted through a screen may be closer to the preset color, which can meet the requirements for color of the display panel in application scenarios.

### CROSS-REFERENCE TO RELATED APPLICATIONS

The present application claims priority to Chinese Patent Application No. 202410250937.8, entitled “DISPLAY PANEL AND DISPLAY DEVICE” and filed on Mar. 5, 2024, the entire contents of which is incorporated herein by reference.

### FIELD

The present application relates to the field of display technologies, and in particular to a display panel and a display device.

### BACKGROUND

With the development of display technologies, people have higher and higher requirements for display screens. For example, transparent display screens, in addition to having display functions, should also allow people to view what is behind the screen, which can enhance the display effect and make the scenarios cooler. This is one of the important development directions in the future.

However, the existing transparent display panels have the problem of incapability to meet the requirements for color of display panels in different application scenarios.

### SUMMARY

In view of this, the present application aims at providing a display panel and a display device, which can meet the requirements for color of display panels in different application scenarios.

One embodiment of the present application provides a display panel. The display panel includes:
pixel regions and light-transmitting regions, and the light-transmitting regions are located between adjacent pixel regions;
the light-transmitting regions each include an adjustment sub-region; and the transmittance of a light adjustment layer in the adjustment sub-region to light of a preset color is greater than the transmittance of the light adjustment layer in regions in the light-transmitting region other than the adjustment sub-region to the light of the preset color.

Another embodiment of the present application further provides a display device. The display device includes a display panel as described in the embodiments of the present application.

### BRIEF DESCRIPTION OF THE DRAWINGS

By providing a more detailed description of the embodiments of the present application with reference to the drawings, the above embodiments of the present application will become more apparent. The drawings are intended to provide further understanding of the embodiments of the present application and constitute a part of the specification, and, together with the embodiments of the present application, are used to illustrate the present application but do not constitute a limitation to the present application. In the drawings, the same reference numerals generally represent the same components or steps.

FIG. 1 is a schematic diagram of a planar structure of a display panel according to an embodiment of the present application;

FIG. 2 is a schematic diagram of a cross-sectional structure of a light-transmitting region of a display panel according to an embodiment of the present application;

FIG. 3 is a graph of the thickness of a light extraction layer versus the transmittance to a first color light according to an embodiment of the present application;

FIG. 4 is a schematic diagram of a planar structure of a light-transmitting region of a display panel according to another embodiment of the present application;

FIG. 5 is a schematic diagram of a cross-sectional structure of a light-transmitting region of a display panel according to another embodiment of the present application;

FIG. 6 is a schematic diagram of a planar structure of a light-transmitting region of a display panel according to another embodiment of the present application;

FIG. 7 is a schematic diagram of a cross-sectional structure of a light-transmitting region of a display panel according to another embodiment of the present application;

FIG. 8 is a schematic diagram of a planar structure of a light-transmitting region of a display panel according to another embodiment of the present application;

FIG. 9 is a schematic diagram of a cross-sectional structure of a light-transmitting region of a display panel according to another embodiment of the present application; and

FIG. 10 is a graph of the thickness of a planarization layer versus the transmittance to light of different wavelengths according to an embodiment of the present application.

### DETAILED DESCRIPTION

Unless otherwise defined, the terms used in the embodiments of the specification shall have the common meanings as understood in the art to which the specification belongs. “First”, “second”, and like words used in the embodiments of the specification do not indicate any order, quantity, or importance, but are merely employed to avoid confusion among constituent elements.

Unless the context requires otherwise, throughout the specification, “a plurality of” means “at least two”, and “comprising/including” is to be interpreted as an open, inclusive meaning, that is, “including, but not limited to”. In the description of the specification, “one embodiment”, “some embodiments”, “exemplary embodiment”, “example”, “specific example”, or “some examples” and other terms are intended to indicate that specific features, structures, materials, or characteristics associated with the embodiment or example are included in at least one embodiment or example of the specification. The schematic expressions of the above terms do not necessarily refer to the same embodiments or examples.

The embodiments of the specification will be clearly and completely described below with reference to the drawings in the embodiments of the specification. Apparently, the embodiments described are merely some rather than all of the embodiments of the specification.

With the development and progress of display technologies, transparent display panels have become an increasingly important development trend. Transparent display panels can bring more conveniences to people, such as vehicle windows, museum showcases, shopping mall windows and augmented reality (AR) devices. While providing display information for people, it is also convenient for people to view the objects or scenery behind the display panel through the display panel, which enriches the visual information and makes the scenario cooler and more impressive technologically.

However, the transmittance of existing transparent display panels is low. In some application scenarios, the appearance of the display panel is often required to present a color that matches the application scenario to enhance the user's visual experience. However, directly increasing the screen color will result in a transmittance that cannot meet usage requirements. Therefore, how to meet the requirements for color of display panels in different application scenarios is an issue that needs to be solved urgently.

To this end, the present application provides a solution that can effectively enhance the screen color. By providing an adjustment sub-region in a light-transmitting region of a display panel and setting the transmittance of a light adjustment layer in the adjustment sub-region to light of a preset color to be greater than the transmittance of the light adjustment layer in regions in the light-transmitting region other than the adjustment sub-region to the light of the preset color, that is, enhancing the transmittance of the light-transmitting region of the display panel to the light of the preset color, the color of the light being transmitted through the display panel may be closer to the preset color, which meets the requirements for color of the display panel in application scenarios and thus the user's usage requirements.

An embodiment of the present application provides a display panel. FIG. 1 is a schematic diagram of a planar structure of a display panel according to an embodiment of the present application. As shown in FIG. 1, the display panel may include at least multiple pixel regions S and multiple light-transmitting regions G, each of the light-transmitting regions G being located between adjacent pixel regions S. The pixel region S may include a pixel island for luminous display. In one embodiment, connecting lines are provided between adjacent pixel regions S, and the light-transmitting region G may be a region having a light-transmitting function enclosed by four pixel regions S and the connecting lines. Accordingly, the display panel is a transparent display panel that enables transparent display.

The adjacent pixel regions S are connected via a connecting line region. At least three pixel regions S and at least three connecting line regions between the adjacent pixel regions S are arranged on the periphery of the light-transmitting region G.

The pixel regions S are arranged in an array on the display panel. Adjacent pixel regions S in the same row are connected via a connecting line region, and adjacent pixel regions S in the same column are connected via a connecting line region. When the connecting line region is opaque, a light-transmitting region G is formed by at least three pixel regions located in different rows and columns and connecting line regions located between adjacent pixel regions S. For example, the light-transmitting region G may be triangular, quadrangular, pentagonal, hexagonal, etc.

The light-transmitting region G may include an adjustment sub-region T. The transmittance of a light adjustment layer in the adjustment sub-region T to light of a preset color is greater than the transmittance of the light adjustment layer in regions in the light-transmitting region other than the adjustment sub-region T to the light of the preset color.

The light of the preset color may be blue, green, red or white, etc.

Compared with traditional transparent display panels, the adjustment sub-region T is provided in the light-transmitting region G, and the transmittance of the light adjustment layer in the adjustment sub-region T to the light of the preset color is greater than the transmittance of the light adjustment layer in regions in the light-transmitting region other than the adjustment sub-region T to the light of the preset color. That is, the transmittance of the adjustment sub-region T in the light-transmitting region G to the light of the preset color is increased, which increases the transmittance of the light-transmitting region G to the light of the preset color as a whole, and the color of the light-transmitting region G of the display panel is closer to the preset color. In this way, display panels of corresponding colors can be customized according to the requirements in different application scenarios, which meets requirements for color without reducing the transmittance of the display panel, to improve the user experience.

For example, if the current application scenario has a bluish color, a display panel with blue light as the light of a preset color can be used, and the transmittance of the light adjustment layer in the adjustment sub-region T to blue light is greater than the transmittance of the light adjustment layer in regions in the light-transmitting region other than the adjustment sub-region T to blue light, that is, the blue light transmittance in the light-transmitting region G is increased, and the color of the light-transmitting region G is closer to blue, and thus the display panel presents a color that is closer to blue. Placing a bluish display panel in a bluish-colored application scenario can make the display panel better match the application scenario.

Also, under the influence of material properties, part of the material of the display panel will gradually turn yellow as the usage time increases, causing the display panel to gradually turn yellow in appearance, which impairs the appearance and display effect. To this end, the light of a preset color may be set to blue light, and by increasing the transmittance of the display panel to blue light, the yellow color of the appearance of the display panel can be harmonized, to reduce the yellowness of the display panel, to improve the display effect.

In addition, adjusting the thickness of the light adjustment layer to adjust the color of the display panel is not only simple in process and easy to implement, but also can achieve the cost-saving effect.

In some embodiments, the pixel region S and the light-transmitting region G may each include a light adjustment layer. The thickness of the light adjustment layer in the pixel region S may be the same as or different from the thickness of the light adjustment layer in the light-transmitting region G.

It should be noted that the thickness of the light adjustment layer in the pixel region S and the thickness of the light adjustment layer in the light-transmitting region G may be set according to actual requirements. The thickness of the light adjustment layer in the light-transmitting region G can be adjusted according to the requirements of transmittance to light of different colors.

In order to improve the match of the display panel to the application scenario, in some embodiments, the area of the adjustment sub-region may be greater than the area of the other region in the light-transmitting region, to increase the light transmittance to the light of the preset color, making the screen color of the display panel closer to the preset color.

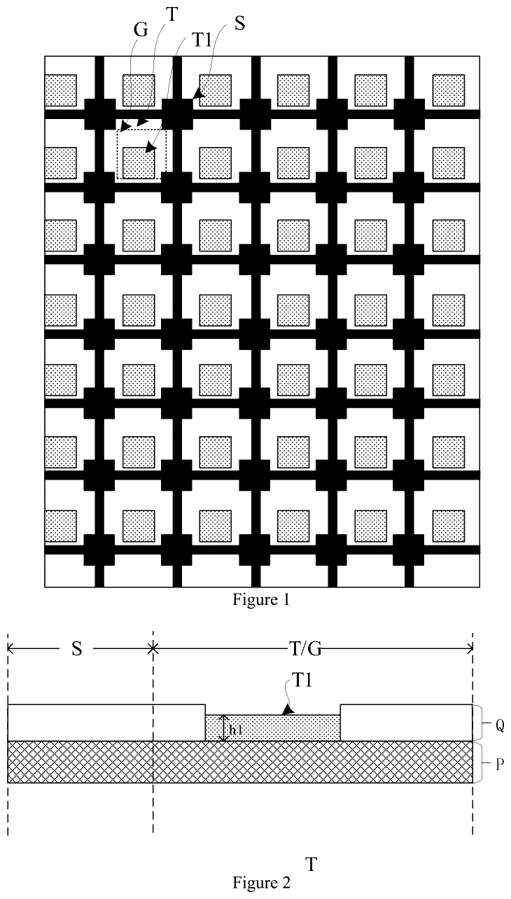

In one embodiment, in order to further improve the match of the display panel to the application scenario, as shown in FIG. 2, the adjustment sub-region T may include a first sub-region T1; and the transmittance of the light adjustment layer in the first sub-region T1 to the a first color light is greater than the transmittance of the light adjustment layer in regions in the adjustment sub-region other than the first sub-region T1 to the first color light.

During implementation, the area of a projection of the first sub-region T1 on the base board may be greater than the area of a projection of regions in the light-transmitting region T other than the first sub-region T1 on the base board.

In this way, increasing the proportion of area of the first sub-region T1 in the light-transmitting region T can effectively increase the transmittance to the first color light to enhance the first color.

It should be understood that the area of the projection of the first sub-region T1 on the base board being greater than the area of the projection of regions in the adjustment sub-region T other than the first sub-region T1 on the base board means that the first sub-region T1 may be the entire light-transmitting region G, or the first sub-region T1 may be part of the light-transmitting region G. The higher the proportion of area of the first sub-region T1 in the light-transmitting region G is, the darker the first color presented by the display panel is. During application, the proportion of area of the first sub-region T1 in the light-transmitting region G may be set according to actual requirements, which is not specifically limited herein.

In order to increase the transmittance of the first sub-region T1 in the transparent region to the first color light, in some embodiments, as shown in FIG. 2, the thickness of the light adjustment layer Q in the first sub-region T1 may be a first preset thickness h1, and the range of the first preset thickness is the thickness of the light adjustment layer that provides that the transmittance to the first color light being greater than a first preset threshold.

It should be noted that the light adjustment layer Q has different thicknesses and its transmittance to the first color light will also be different, and the range of the first preset thickness may be determined based on a curve of the thickness of the light adjustment layer Q versus the transmittance to the first color light in the first sub-region T1.

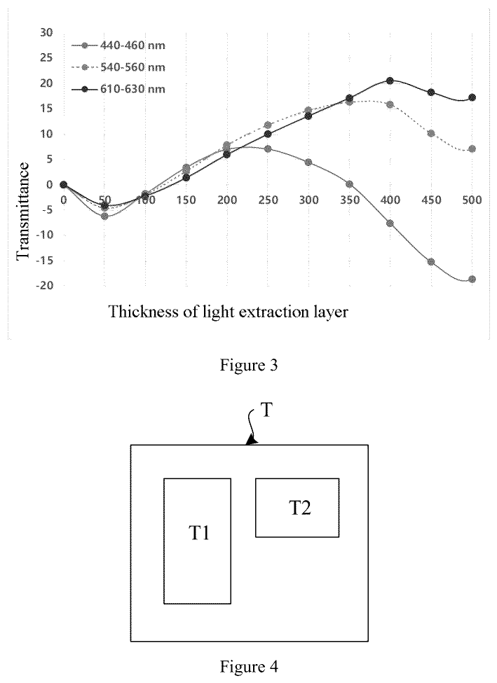

In one embodiment, taking the light adjustment layer Q as the light extraction layer as an example, as shown in FIGS. 2 and 3, the horizontal axis is the thickness of the light extraction layer, the vertical axis is the filtration rate of light, 440-460 nm is the wavelength of blue light, 550-560 nm is the wavelength of green light, and 610-630 nm is the wavelength of red light. As shown in the figures, for the light of different colors, as the thickness of the light extraction layer increases, the transmittance thereof also changes accordingly. For blue light, its transmittance is in a higher range when the thickness is 200-250 angstroms, for red light, its transmittance is in a higher range when the thickness is 350-450 angstroms, and for green light, its transmittance is in a higher range when the thickness is 300-400 angstroms. Therefore, when the first color light is blue light, the transmittance when the thickness of the light extraction layer is 200 angstroms or 250 angstroms may be set to a first preset threshold and the first sub-region T1 of the first preset thickness has a higher blue light transmittance than the other regions in the adjustment sub-region T. When the first color light is red light, the transmittance when the thickness of the light extraction layer is 350 angstroms or 450 angstroms may be set to a first preset threshold and the first sub-region T1 of the first preset thickness has a higher red light transmittance than the other regions in the adjustment sub-region T. Similarly, when the first color light is green light, the transmittance when the thickness of the light extraction layer is 300 angstroms or 400 angstroms may be set to a first preset threshold and the first sub-region T1 of the first preset thickness has a higher green light transmittance than the other regions in the adjustment sub-region T. At the same time, in the light-transmitting region G, the film thickness of the light extraction layer in regions other than the first sub-region T1 may be consistent with the film thickness of the light extraction layer in the pixel region.

During implementation, the first preset threshold may be set according to actual requirements, which is not specifically limited herein.

In some embodiments, as shown in FIG. 4, the adjustment sub-region T may further include a second sub-region T2; and the transmittance of the light adjustment layer Q in the second sub-region T2 to a second color light is greater than the transmittance of the light adjustment layer Q in regions other than the second sub-region T2 to the second color light.

The second color light may be of the same color as the first color light, or may be of a different color from the first color light. When the second color light is the same as the first color light, the transmittance of the display panel to the first color light can be further enhanced, and the appearance color of the display panel is closer to the first color. When the second color light is different from the first color light, since the transmittance of the light adjustment layer Q in the second sub-region T2 to the second color light is greater than the transmittance of the light adjustment layer Q in regions other than the second sub-region T2 to the second color light, the transmittance of the display panel to the first color light and the transmittance to the second color light are effectively improved.

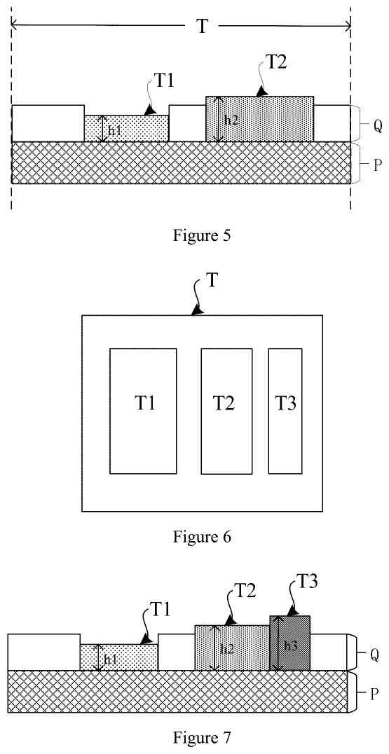

In some embodiments, as shown in FIG. 5, the thickness of the light adjustment layer Q in the second sub-region T2 is a second preset thickness h2, and the range of the second preset thickness is the thickness range of the light adjustment layer Q in which the transmittance to the second color light is greater than the second preset threshold.

It should be understood that the change in thickness of the light adjustment layer Q in the second sub-region T2 will also influence its transmittance to the second color light. Therefore, the range of the second preset thickness may be determined based on a curve of the thickness of the light adjustment layer Q versus the transmittance to the second color light in the second sub-region T2.

In one embodiment, the second preset thickness h2 may be determined according to a curve of the thickness of the light adjustment layer Q versus the transmittance to the second color light. For example, from the curve of the thickness of the light adjustment layer Q versus the transmittance to the second color light, it can be determined that when the thickness of the light adjustment layer Q is in the range of 330-440 angstroms, the transmittance to the second color light is greater than the second preset threshold, then it can be determined that the range of the second preset thickness is 330-440 angstroms, and the second preset thickness can be selected from 330-440 angstroms.

The second preset threshold may be set according to actual requirements, which is not specifically limited herein.

It should be understood that when the first color light is different from the second color light, since the light of different colors have different light transmittance curves, the film thickness corresponding to the curve peak will also be different. Therefore, the first preset thickness has a different thickness value from the second preset thickness.

In some embodiments, as shown in FIGS. 6 and 7, the adjustment sub-region T may further include a second sub-region T2 and a third sub-region T3; the transmittance of the light adjustment layer Q in the second sub-region T2 to a second color light is greater than the transmittance of the light adjustment layer Q in regions other than the second sub-region T2 to the second color light; and the transmittance of the light adjustment layer Q in the third sub-region T3 to a third color light is greater than the transmittance of the light adjustment layer Q in regions other than the third sub-region T3 to the third color light.

Thus, in the first sub-region T1, the transmittance to the first color light is greater than the transmittance to the first color light in regions other than the first sub-region T1; in the second sub-region T2, the transmittance to the second color light is greater than the transmittance to the second color light in regions other than the second sub-region T2; and in the third sub-region T3, the transmittance to the third color light is greater than the transmittance to the third color light in regions other than the third sub-region T3. By adjusting and increasing the transmittance of the sub-regions in the adjustment sub-region T to the light of different colors, the transmittance of the light-transmitting region G to the light of the corresponding color can be effectively improved, to improve the display effect of the display panel.

As shown in FIG. 7, the thickness of the light adjustment layer Q in the second sub-region T2 may be a second preset thickness h2, and the range of the second preset thickness h2 is the thickness range of the light adjustment layer Q in which the transmittance to the second color light is greater than a second preset threshold. In this way, the thickness of the light adjustment layer Q in the second sub-region T2 can be adjusted to adjust the transmittance to the second color light in the second sub-region T2, and the transmittance to the second color light in the second sub-region T2 is greater than the transmittance to the second color light in regions other than the second sub-region T2, which increases the transmittance to the second color light in the light-transmitting region G.

Similarly, the thickness of the light adjustment layer Q in the third sub-region T3 may be a third preset thickness h3, and the range of the third preset thickness h3 is the thickness range of the light adjustment layer Q in which the transmittance to the third color light is greater than the third preset threshold. In this way, the thickness of the light adjustment layer Q in the third sub-region T3 can be adjusted to adjust the transmittance to the third color light in the third sub-region T3, and the transmittance to the third color light in the third sub-region T3 is greater than the transmittance to the third color light in regions other than the third sub-region T3, which increases the transmittance to the third color light in the light-transmitting region G.

During implementation, the first color light, the second color light and the third color light may be light of the same color or light of different colors. For example, the first color light, the second color light and the third color light may all be blue light, thus effectively ameliorating the yellowing problem of the display panel. For another example, the first color light, the second color light and the third color light may be blue light, green light and red light, respectively, which enhances the ambient light transmittance of the display panel, to improve the display effect and enhancing the integration effect with the environment.

When the first color light, the second color light and the third color light are of three different colors, the first preset thickness, the second preset thickness and the third preset thickness have different thickness values.

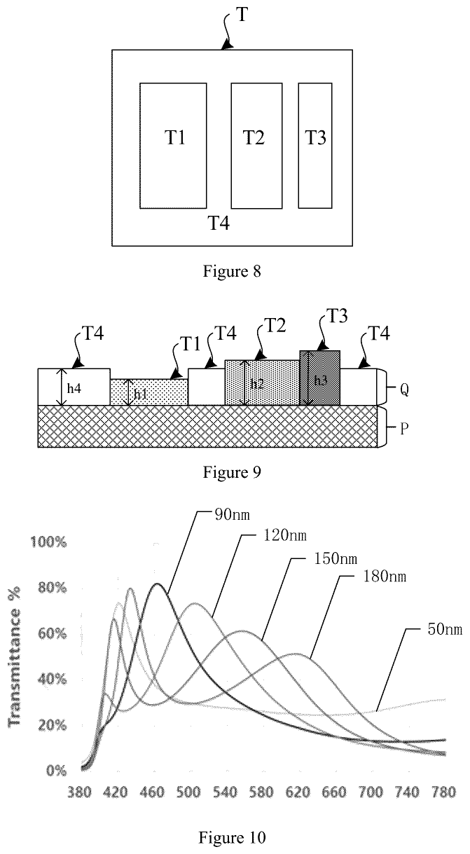

In some embodiments, as shown in FIGS. 8 and 9, the adjustment sub-region T may further include a fourth sub-region T4; and the fourth sub-region T4 is the region in the adjustment sub-region T other than the first sub-region T1, the second sub-region T2, and the third sub-region T3.

During implementation, the thickness of the light adjustment layer Q in the fourth sub-region T4 may be set to a fourth preset thickness h4, and the range of the fourth preset thickness h4 is the thickness range of the light adjustment layer Q in which the transmittance to the light of the fourth color is greater than a fourth preset threshold. In this way, the thickness of the light adjustment layer Q in the fourth sub-region T4 can be adjusted to adjust the transmittance to the light of the fourth color in the fourth sub-region T4, and the transmittance to the light of the fourth color in the fourth sub-region T4 is greater than the transmittance to the light of the fourth color in regions other than the fourth sub-region T4, which increases the transmittance to the light of the fourth color in the light-transmitting region G.

The light of the fourth color is different from the first color light, the second color light and the third color light, that is, the thickness of the light adjustment layer in the fourth sub-region T4 is different from the thicknesses of the light adjustment layer in the first sub-region T1, the second sub-region T2 and the third sub-region T3. In this way, the transmittance of the light-transmitting region G can be further increased, to improve the display effect.

In some embodiments, the first color light, the second color light, the third color light and the light of the fourth color may be set to the light of four colors, i.e., blue light, green light, red light and white light, and the local band transmittance of the display panel can be increased according to the proportion of area of the sub-regions corresponding to the light of the colors in the light-transmitting region T. For example, if the screen needs to appear bluish, the area of the sub-region where the blue light is located can be enlarged, while the presence of sub-regions where the light of other colors are located can help increase the transmittance of the display panel to meet the user's usage requirements.

In some embodiments, the area of the projection of the first sub-region T1 on the base board P is greater than the area of the projection of the second sub-region T2 on the base board P, and the area of the projection of the second sub-region T2 on the base board P is greater than the area of the projection of the third sub-region T3 on the base board P, which can increase the transmittance while making the appearance of the display panel closer to the first color to meet the user's usage requirements.

The first color light may be blue, the second color light may be green, and the third color light may be red. Thus, the proportion of the first sub-region T1 in the light-transmitting region T is greater than the second sub-region T2 and the third sub-region T3. The blue color presented by the light transmitting the display panel can harmonize the yellow color produced by the appearance, to improve the display effect of the display panel. At the same time, the proportion of area of the second sub-region T2 in the light-transmitting region T is greater than the proportion of area of the third sub-region T3, which further increases the light transmittance of the display panel.

Also, still referring to FIG. 3, when the light adjustment layer is a light extraction layer, the thickness of the light adjustment layer in the first sub-region may be set to be less than the thickness of the light adjustment layer in the second sub-region, and the thickness of the light adjustment layer in the second sub-region may be set to be less than the thickness of the light adjustment layer in the third sub-region. In one embodiment, the first preset thickness may be set in the range of 200-250 angstroms, the second preset thickness may be set in the range of 300-400 angstroms, and the third preset thickness may be set in the range of 350-450 angstroms and less than the second preset thickness. At this time, the first sub-region T1 has the highest blue light transmittance, the second sub-region T2 has the highest green light transmittance, and the third sub-region T3 has the highest red light transmittance. In this way, the light transmittance of the adjustment sub-region T can be further increased, and thus the light transmittance of the display panel is further increased.

In one embodiment, as shown in FIG. 10, FIG. 10 shows a graph of the change in transmittance to light of different wavelengths in a planarization layer of different thicknesses, in which the horizontal axis is the wavelength of light, and the vertical axis is the filtration rate of light. Since 440-460 nm is the wavelength of blue light, 550-560 nm is the wavelength of green light, and 610-630 nm is the wavelength of red light, as shown in the figure, for a wavelength of 440-460 nm, when the planarization layer has a thickness of 90 nm, its light transmittance is in a high state; for a wavelength of 550-560 nm, when the planarization layer has a thickness of 150nm, its light transmittance is in a high state; and for a wavelength of 610-630 nm, when the planarization layer has a thickness of 180 nm, its light transmittance is in a high state. Therefore, when the light adjustment layer is a planarization layer, with the first color light being blue, the second color light being green, and the third color light being red, the thickness of the planarization layer in the first sub-region may be 90 nm, the thickness in the second sub-region may be 150 nm, and the thickness in the third sub-region may be 180 nm. At this time, the first sub-region T1 has the highest blue light transmittance, the second sub-region T2 has the highest green light transmittance, and the third sub-region T3 has the highest red light transmittance. This further increases the light transmittance of the display panel.

In practical application, the area ratio of the projections of the first sub-region T1, the second sub-region T2 and the third sub-region T3 on the base board P may be 7:2:1. The inventor has experimentally verified that when the area ratio of the projections of the first sub-region T1, the second sub-region T2 and the third sub-region T3 on the base board P is 7:2:1, the light transmittance of the display panel and the improvement on the yellowing problem of the display panel are better.

In some embodiments, the pixel region S may include a first electrode layer, a common layer, a light-emitting layer, a second electrode layer, and a light extraction layer which are sequentially stacked; and the light-transmitting region G may include one or more of the common layer, the second electrode layer, and the light extraction layer.

In one embodiment, the display panel may further include a substrate arranged in the pixel region and the light-transmitting region, a drive device layer located on one side of the substrate, a planarization layer located on one side of the drive device layer, and an encapsulation layer located on a side of the second electrode layer away from the substrate.

The first electrode layer is located on a side of the planarization layer away from the substrate, and the first electrode layer is discretely arranged on the planarization layer. In one embodiment, the first electrode layer may be an anode layer, and the second electrode layer may be a cathode layer.

The light adjustment layer Q may include at least one of the planarization layer, the common layer, the second electrode layer, the light extraction layer, and the encapsulation layer. The display panel further includes a pixel defining layer located on the planarization layer. The pixel defining layer includes of pixel openings exposing the first electrode layer, the common layer covers the first electrode layer and the pixel definition layer, a light-emitting layer located in the pixel opening is arranged on a side of the common layer away from the first electrode layer, a second electrode layer is arranged on a side of the light-emitting layer away from the common layer, the second electrode layer covers the common layer, a light extraction layer is arranged on a side of the second electrode layer away from the common layer, and an encapsulation layer is arranged on a side of the light extraction layer away from the second electrode layer, to realize encapsulation protection of sub-pixels in the pixel openings. The encapsulation layer is an inorganic encapsulation layer prepared by a chemical vapor deposition process.

In some embodiments, under white light or natural light, to ensure the light transmittance of the display panel, the light adjustment layer may be a combination of a common layer, a second electrode layer, a light extraction layer and an encapsulation layer, and the thickness of the common layer in the first sub-region may be selected from the range of 160-230 nm, the thickness of the second electrode layer may be selected from the range of 6-12 nm, the thickness of the light extraction layer may be selected from the range of 15-25 nm, and the thickness of the encapsulation layer may be selected from the range of 3-7 nm; in the second sub-region, the thickness of the common layer may be selected from the range of 200-250 nm, the thickness of the second electrode layer may be selected from the range of 5-15 nm, the thickness of the light extraction layer may be selected from the range of 35-45 nm, and the thickness of the encapsulation layer may be selected from the range of 5-9 nm; in the third sub-region, the thickness of the common layer may be selected from 280 to 320 nm, the thickness of the second electrode layer may be selected from the range of 10-15 nm, the thickness of the light extraction layer may be selected from the range of 40-50 nm, and the thickness of the encapsulation layer may be selected from the range of 6-12 nm; and in the fourth sub-region, the thickness of the common layer may be selected from the range of 150-200 nm, the thickness of the second electrode layer may be selected from the range of 5-10 nm, the thickness of the light extraction layer may be selected from the range of 45-55 nm, and the thickness of the encapsulation layer may be selected from the range of 3-8 nm.

In some embodiments, the thickness of the adjustment layer in the first sub-region may be: the common layer is 190 nm, the second electrode layer is 9 nm, the light extraction layer is 20 nm and the encapsulation layer is 5 nm. The thickness of the light adjustment layer in the second sub-region may be: the common layer is 230 nm, the second electrode layer is 10 nm, the light extraction layer is 40 nm and the encapsulation layer is 6 nm. The thickness of the light adjustment layer in the third sub-region may be: the common layer is 300 nm, the second electrode layer is 13 nm, the light extraction layer is 45 nm, and the encapsulation layer is 8 nm. The thickness of the light adjustment layer in the fourth sub-region may be: the common layer is 170 nm, the second electrode layer is 7 nm, the light extraction layer is 50 nm, and the encapsulation layer is 5 nm.

It should be noted that the light adjustment layer Q includes at least one of the planarization layer, the common layer, the second electrode layer, the light extraction layer and the encapsulation layer, and when the adjustment sub-region T includes at least two sub-regions, the at least two sub-regions can be located in the same film layer of the display panel or in different film layers. For example, the light adjustment layer Q includes a light extraction layer and a second electrode layer, and the adjustment sub-region T includes a first sub-region T1 and a second sub-region T2. The first sub-region T1 and the second sub-region T2 may be both located in the light extraction layer, or both located in the second electrode layer, or respectively located in the light extraction layer and the second electrode layer. The light adjustment layer Q may also be an inorganic film layer in the drive device layer, and, for example, may include at least one of an interlayer dielectric layer, a capacitor insulation layer, a gate insulation layer, etc. The common layer may include at least one of an electron injection layer, an electron transport layer, a hole transport layer, and a hole injection layer. In some embodiments, the light adjustment layer Q may be a light extraction layer. During implementation, for the light extraction layer, a fine metal mask (FMM) evaporation process technology can be used to achieve thickness distribution in different sub-regions, which increases the transmittance of a single sub-region to a single type of light.

In one embodiment, the light extraction layer may include at least two light extraction sub-layers, and the refractive indexes of at least two light extraction sub-layers gradually increase in a direction away from the base board P, which further increases the transmittance to light in the light-transmitting region T.

On the other hand, the refractive indexes of at least two light extraction sub-layers in the pixel region gradually decrease in the direction away from the base board P, that is, the refractive index of the light extraction sub-layer close to the base board P is greater than the refractive index of the light extraction sub-layer away from the base board P, which further increases the light transmittance in the pixel region.

During implementation, the sub-regions in the light-transmitting region T may be simultaneously arranged in one of the at least two light extraction sub-layers, or may be separately arranged in any multiple layers of the at least two light extraction sub-layers.

An embodiment of the present application provides a display device. The display device includes a display panel according to any of the above embodiments. The display device may be a smart phone, or a tablet computer or a digital camera, or a car front window, etc., which will not be described in detail herein.

The various embodiments in the specification are described in a progressive manner, and each embodiment focuses on the differences from other embodiments. The same or similar parts between the various embodiments may be referenced to each other.

Various modifications to these embodiments are apparent in the art, and the general principle defined herein may be practiced in other embodiments without departing from the spirit or scope of the present application. Therefore, the present application is not limited to the embodiments described herein but is to be accorded with the broadest scope consistent with the principle and novel features disclosed herein.

What is claimed is:

1. A display panel, comprising:
a plurality of pixel regions and a plurality of light-transmitting regions, and each of the light-transmitting regions being located between adjacent pixel regions;
wherein each of the light-transmitting regions comprises an adjustment sub-region; and the transmittance of a light adjustment layer in the adjustment sub-region to light of a preset color is greater than the transmittance of the light adjustment layer in regions in the light-transmitting region other than the adjustment sub-region to the light of the preset color.

2. The display panel according to claim 1, wherein the pixel region and the light-transmitting region each comprise the light adjustment layer;
the adjacent two pixel regions are connected via a connecting line region, and at least three pixel regions and at least three connecting line regions between the adjacent pixel regions are arranged on the periphery of the light-transmitting region; and
an area of the adjustment sub-region is greater than an area of the other regions in the light-transmitting region.

3. The display panel according to claim 1, wherein the adjustment sub-region comprises a first sub-region, and the transmittance of the light adjustment layer in the first sub-region to a first color light is greater than the transmittance of the light adjustment layer in regions in the adjustment sub-region other than the first sub-region to the first color light; and
the light adjustment layer in the first sub-region has a first preset thickness, and the first preset thickness provides that the transmittance to the first color light is greater than a first preset threshold.

4. The display panel according to claim 3, wherein the adjustment sub-region further comprises a second sub-region, and the transmittance of the light adjustment layer in the second sub-region to a second color light is greater than the transmittance of the light adjustment layer in regions in the adjustment sub-region other than the second sub-region to the second color light.

5. The display panel according to claim 4, wherein the light adjustment layer in the second sub-region has a second preset thickness, and the second preset thickness provides that the transmittance to the second color light is greater than a second preset threshold.

6. The display panel according to claim 5, wherein the first preset thickness and the second preset thickness have different thickness values.

7. The display panel according to claim 6, wherein the adjustment sub-region further comprises a second sub-region and a third sub-region;
the transmittance of the light adjustment layer in the second sub-region for a second color light is greater than the transmittance of the light adjustment layer in regions in the adjustment sub-region other than the second sub-region to the second color light; the transmittance of the light adjustment layer in the third sub-region to a third color light is greater than the transmittance of the light adjustment layer in regions in the adjustment sub-region other than the third sub-region to the third color light.

8. The display panel according to claim 7, wherein the thickness of the light adjustment layer in the second sub-region is a second preset thickness, and the range of the second preset thickness is a thickness range of the light adjustment layer in which the transmittance to the second color light is greater than a second preset threshold.

9. The display panel according to claim 8, wherein the thickness of the light adjustment layer in the third sub-region is a third preset thickness, and the range of the third preset thickness is a thickness range of the light adjustment layer in which the transmittance for the third color light is greater than a third preset threshold.

10. The display panel according to claim 9, wherein the first preset thickness, the second preset thickness and the third preset thickness have different thickness values.

11. The display panel according to claim 10, wherein the adjustment sub-region further comprises a fourth sub-region; the fourth sub-region is a region in the adjustment sub-region other than the first sub-region, the second sub-region and the third sub-region.

12. The display panel according to claim 11, wherein the thickness of the light adjustment layer in the fourth sub-region is a fourth preset thickness, and the range of the fourth preset thickness is a thickness range of the light adjustment layer in which the transmittance for the light of a fourth color is greater than a fourth preset threshold.

13. The display panel according to claim 12, wherein the first preset thickness, the second preset thickness, the third preset thickness and the fourth preset thickness have different thickness values.

14. The display panel according to claims 1, wherein the pixel region comprises a first electrode layer, a common layer, a light-emitting layer, a second electrode layer, and a light extraction layer which are sequentially stacked; and
the light-transmitting region comprises one or more of the common layer, the second electrode layer and the light extraction layer.

15. The display panel according to claims 14, wherein further comprising a substrate arranged in the pixel region and the light-transmitting region, a drive device layer located on one side of the substrate, a planarization layer located on one side of the drive device layer, and an encapsulation layer located on a side of the second electrode layer away from the substrate;
wherein the first electrode layer is located on a side of the planarization layer away from the substrate; and
the light adjustment layer comprises at least one of the planarization layer, the common layer, the second electrode layer, the light extraction layer, and the encapsulation layer.

16. The display panel according to claims 15, wherein the light adjustment layer further comprises at least one of an interlayer dielectric layer, a gate insulation layer and a capacitor insulation layer in the drive device layer.

17. The display panel according to claims 1, wherein the light adjustment layer comprises a light extraction layer;
the light extraction layer comprises at least two light extraction sub-layers; and
the refractive indexes of the at least two light extraction sub-layers in the light-transmitting region gradually increase in a direction away from a base board; and the refractive indexes of the at least two light extraction sub-layers in the pixel region gradually decrease in the direction away from the base board.

18. The display panel according to claim 17, wherein the area of a projection of the first sub-region on the base board is greater than the area of a projection of regions in the adjustment sub-region other than the first sub-region on the base board.

19. The display panel according to claim 7, wherein the area of the projection of the first sub-region on the base board is greater than the area of a projection of the second sub-region on the base board; and the area of the projection of the second sub-region on the base board is greater than the area of a projection of the third sub-region on the base board; and
the first color light is blue, the second color light is green, and the third color light is red.

20. The display panel according to claim 19, wherein an area ratio of the projections of the first sub-region, the second sub-region and the third sub-region on the base board is 7:2:1; and
the light adjustment layer comprises a light extraction layer, the thickness of the light adjustment layer in the first sub-region is less than the thickness of the light adjustment layer in the second sub-region, and the thickness of the light adjustment layer in the second sub-region is less than the thickness of the light adjustment layer in the third sub-region.
